(19) United States
(12) Patent Application Publication
(10) Pub. No.: US 2025/0052804 A1
(43) Pub. Date: Feb. 13, 2025

(54) System for online monitoring of one or more electric cables in an electrical distribution grid

(71) Applicant: NEXANS, Courbevoie (FR)

(72) Inventors: Moussa KAFAL, Les Ulis (FR); Samuel GRIOT, LYON (FR); Aymeric ANDRE, LYON (FR); Olivier PINTO, Francheville (FR)

(21) Appl. No.: 18/763,657

(22) Filed: Jul. 3, 2024

(30) Foreign Application Priority Data
Jul. 4, 2023 (FR) 2307089

(51) Int. Cl. G01R 31/08

(52) U.S. Cl. CPC G01R 31/083

(57) ABSTRACT

A system for online monitoring of an assembly of electric cables (1) which are connected in series in an electrical distribution grid. The system has a central unit (2) located on a portion of the assembly and data acquisition units (3ₐ, 3_{b}, 3_{c}) spread along the cables (1) at predefined positions. The system has subassemblies of measurement sensors (4ₐ₋₁-4ₐ₋₂, 4_{b-1}-4_{b-4}, 4_{c-1}), the sensors of a subassembly being associated with the same acquisition unit and spread over a portion of the cables in the vicinity of the acquisition unit, the number and the type of sensors of a subassembly varying according to the position of the acquisition unit with which these sensors are associated and the size of the portion. Each acquisition unit is configured to receive and preprocess, under the command of the central unit, measurements originating from the sensors which are associated with it, and to transmit the preprocessed measurements to the central unit.

### RELATED APPLICATION

This application claims the benefit of priority from French Patent Application No. 23 07089, filed on Jul. 4, 2023, the entirety of which is incorporated by reference.

### TECHNICAL FIELD

The present invention relates to the general field of monitoring the correct operation of the elements which are present in an electrical distribution grid, notably the electric cables, and more specifically a system for online monitoring of an assembly comprising one or more electric cables which are connected in series in an electrical distribution grid.

### Technological Background

The increase in the demand for electricity, due to population growth, economic development and the evolution of modes of consumption, requires growing investment in electricity distribution grids. In these grids, each time fraction of power which is not distributed represents a financial loss factor. Electricity distribution is also the market which experiences the largest number of failures for various reasons (geographical scope, variety of technologies, installation carried out by third parties etc.).

Medium-voltage (MV) electric cables are an integral part of the electricity distribution grid which covers vast areas and delivers large amounts of power. The share of underground MV electric cables is increasing considerably, notably because of their reliability, their safety, their longer service life, etc. The uninterrupted operation of underground MV grids is therefore of crucial importance for the overall reliability of the system. Nevertheless, accessing these cables is not easy and is accompanied by a high cost, all the more so given that local cellular connectivity is impossible, apart from at the ends of the cables or on rare occasions (junction wells, etc.).

The electric cables must be able to transmit as much power as possible in order to meet the fluctuating demands of the various markets and environments—in particular now that power transport needs are evolving by virtue of the increased deployment of new uses of the grid, which are not limited to injections of renewable energy resources (RERs), electric vehicles (EVs), etc. This latter phenomenon may reduce technical margins and, in some cases, make the cables operate dynamically depending on the most unfavourable choke point in terms of maximum temperature (hot spot).

Moreover, climate change has recently been accompanied by more intense and more serious unfavourable environmental conditions (heat waves, floods, etc.), which has caused unprecedented levels of stress on the electrical grid, which are accompanied by an increase in failures and an acceleration of the ageing rate. This has highlighted the increased importance of the resilience of electrical grids. The subject is becoming more and more pressing since it guarantees a reliable electricity supply, which is essential for supporting economic activity, and protects public safety, in particular in times of crisis.

First of all, it is essential to make every effort to avoid cable failures, since they may be very costly, not only in terms of repair costs, but also in terms of revenue loss and impact on the brand image of power distributors. In the event of a failure, it is also essential to locate this failure and rectify it as quickly as possible without having to close the grids, which would cause an interruption of the electric power supply and losses. Consequently, non-intrusive online monitoring systems are essential for avoiding such problems appearing.

Temperature and the mechanical, acoustic and electrical profiles of an MV electrical distribution grid are all important parameters which may be monitored in order to make it possible to thoroughly inspect and analyse the potential risks which are likely to affect a cable, an accessory etc.

For example, an electric cable transporting a high current or operating at a high temperature (heat waves, dry ground etc.) risks undergoing dielectric thermal stress, which may cause an insulation failure. By monitoring the temperature of the cable, it is possible to sense the moment when the cable approaches its maximum temperature and to take the necessary measures to avoid the failure.

Moreover, the acoustic signals in the electric cables are accompanied by a variety of factors, such as an electrical discharge, mechanical stress or changes in temperature, etc. Continuously monitoring the acoustic signals makes it possible to sense these events and to use the information to identify the potential problems in the cable.

Furthermore, the measurements of the strain or stretching of a cable make it possible to quantify the external forces undergone by the cable, such as mechanical stress or changes in temperature. Thus, constantly monitoring the strain of a supply cable makes it possible to sense changes in the state and the performance of the cable, and also the forces which act on it.

Finally, events which are precursors of faults (partial discharges, friction etc.) in electrical grids are generally accompanied by high-frequency transient signals which propagate along the grid, by virtue of the cable itself, which acts as a propagation channel. Monitoring these pulses makes it possible to sense and locate potential weak points and therefore provides an early warning approach.

As of now, a fibre-optic distributed sensing system which is capable of simultaneously implementing, on a cable to be monitored incorporating an optical fibre, distributed temperature sensing (DTS), distributed acoustic sensing (DAS) and distributed strain sensing (DSS) solutions is known. This type of system uses a fibre-optic cable which is incorporated into the electric cable to be monitored and which is covered with materials which are sensitive to temperature, strain and acoustics. By measuring the variations in intensity of the light transmitted by the fibre-optic cable, it is possible to determine the temperature, the strain and the acoustic signals over the whole length of the cable. While it is common for high-voltage cables to be equipped with optical fibres, underground low- or medium-voltage cables are less likely to be equipped with them, the decision to include them depending on the specific requirements of the application (data transmission, etc.), the complexity and the concerns relating to replacement costs. Furthermore, such fibre-optic systems do not make it possible to measure partial discharges.

In addition, the document US 2015/69998 describes a system for online monitoring of an assembly comprising electric cables which are connected in series in an electrical distribution grid, the system comprising a plurality of identical data acquisition units which are spread along the electric cables at predefined positions and able to communicate data to one another. Each data acquisition unit is composed of a housing which may be fixed along the electric cables, this housing incorporating a plurality of measurement sensors which are able to directly or indirectly measure various parameters, for example a current measurement sensor, a surge current measurement sensor, a fault current measurement sensor, an electric field measurement sensor and a line temperature measurement sensor. Such a system does not make it possible either to anticipate failures linked to partial discharges or to sense acoustic signals and/or strains in the cables. Furthermore, such a system does not make it possible to derive a sufficiently accurate temperature profile, except by placing a very large number of housings at a small distance with respect to one another along the cables, in order to measure the temperature at enough points by virtue of the temperature sensor incorporated into the housing.

### SUMMARY OF THE INVENTION

The aim of the present invention is to mitigate the drawbacks of the aforementioned systems by proposing a lower-cost system which can diagnose several types of failures in an assembly of electric cables which are connected in series.

More specifically, the subject of the present invention is a system for online monitoring of an assembly comprising one or more electric cables which are connected in series in an electrical distribution grid, the system comprising a central unit located on a portion of said assembly being monitored and a plurality of data acquisition units which are spread along said one or more electric cables in predefined positions, and being characterized in that it further comprises a plurality of subassemblies of measurement sensors, the measurement sensors of a given subassembly being associated with one and the same data acquisition unit and spread over at least one portion of the length of said one or more electric cables in the vicinity of said one and the same data acquisition unit, in that the number and the type of measurement sensors of a given subassembly vary according to the position of the data acquisition unit with which these measurement sensors are associated and the size of said portion of length, and in that each data acquisition unit is configured to receive and preprocess, during acquisition campaigns carried out under the command of the central unit, measurements originating from the measurement sensors which are associated with it in a given subassembly, and to transmit the received and preprocessed measurements to the central unit.

In one possible embodiment, at least one subassembly of measurement sensors comprises a plurality of measurement sensors of the same type which are spread over said portion of length.

In one possible embodiment, at least one subassembly of measurement sensors comprises two or more temperature sensors and/or two or more acoustic signal sensors which are spread over said portion of length.

In one possible embodiment, at least two subassemblies of measurement sensors comprise an inductive sensor configured to sense pulse events which are caused by partial discharges.

In one possible embodiment, the measurement sensors of a given subassembly transmit their measurements to the data acquisition unit which is associated with them through a wired or wireless communication link.

Each data acquisition unit may advantageously be configured to transmit the received and preprocessed measurements to the central unit via said one or more electric cables.

The system may further comprise a remote unit with which the central unit exchanges data via the Internet, the central unit being configured to transmit data which are based on an aggregation of the received and preprocessed measurements.

The central unit is located, for example, on an end portion of said assembly being monitored.

In one possible embodiment, two consecutive data acquisition units are separated by a distance of the order of one kilometer, and the size of said portion of length is between 50 and 500 metres.

### BRIEF DESCRIPTION OF THE FIGURES

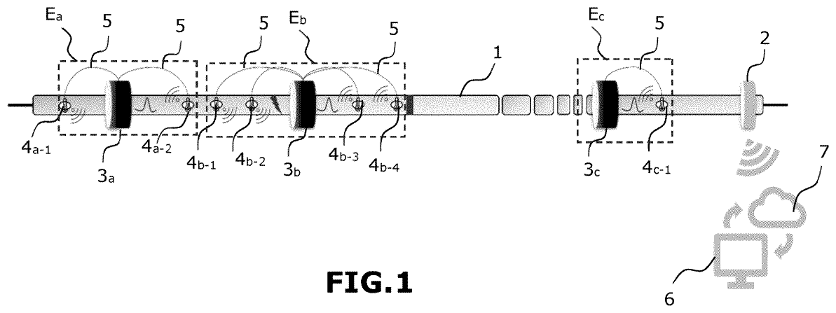

The following description with reference to the appended drawing, which is given by way of non-limiting example, will make it well understood what the invention consists of and how it may be embodied. FIG. 1 illustrates an assembly comprising one or more electric cables 1 and a system for online monitoring of this assembly in accordance with the invention.

### DESCRIPTION OF EMBODIMENT(S)

FIG. 1 partially and schematically illustrates an assembly comprising one or more electric cables 1 which are connected in series in an electrical distribution grid, and a system for online monitoring of this assembly in accordance with the invention. The electrical distribution grid is, for example, a high-voltage or medium-voltage grid, composed of a plurality of electric cables such as the electric cable 1, connection accessories, equipment and/or transformers.

The system comprises a central unit 2 located on a portion of said assembly being monitored. In the case of an underground electrical distribution grid, the central unit 2 is preferably situated on an end portion of the assembly being monitored.

The system also comprises a plurality of data acquisition units, such as the three data acquisition units 3ₐ, 3_{b} and 3_{c}, which are spread along said one or more electric cables 1 in predefined positions. By way of non-limiting example, two consecutive data acquisition units may be separated by a distance of the order of one kilometer.

Each data acquisition unit may be supplied with power either by a battery or by an integrated module for collecting power from the current flowing through the electric cables. The power collection module is particularly advantageous since it does not require that the battery be maintained and makes it possible to avoid costly civil engineering work for accessing the cable. Thus, the acquisition units may be installed on the cable, and the cable buried without other maintenance planned.

The system further comprises a plurality of subassemblies of measurement sensors, such as the first subassembly, composed of the two measurement sensors 4ₐ₋₁ and 4ₐ₋₂, the second subassembly, composed of the four measurement sensors 4_{b-1} to 4_{b-4}, and the third subassembly, comprising the measurement sensor 4_{c-1}.

As illustrated in FIG. 1, the measurement sensors of a given subassembly are associated with one and the same data acquisition unit and spread over at least one portion of the length of said one or more electric cables 1 in the vicinity of said one and the same data acquisition unit. Thus, notably:
the first subassembly, composed of the two measurement sensors 4ₐ₋₁ and 4ₐ₋₂, is associated with the data acquisition unit 3ₐ and forms, with this unit, a subsystem labelled Eₐ in the FIGURE;
the second subassembly, composed of the four measurement sensors 4_{b-1} to 4_{b-4}, is associated with the data acquisition unit 3_{b} and forms, with this unit, a subsystem labelled E_{b} in the FIGURE; and
the third subassembly, comprising the measurement sensor 4_{c-1}, is associated with the data acquisition unit 3_{c} and forms, with this unit, a subsystem labelled E_{c} in the FIGURE.

Each data acquisition unit 3ₐ, 3_{b}, 3_{c} is configured to receive and preprocess, during acquisition campaigns carried out under the command of the central unit 2, measurements originating from the measurement sensors which are associated with it in a given subassembly, and to transmit the received and preprocessed measurements to the central unit 2. In other terms, each subsystem, such as the subsystems Eₐ, E_{b} and E_{c} in the FIGURE, is a slave subsystem which makes it possible to acquire the measurements from the associated measurement sensors spread over the corresponding portion of length of cable, on order of the master unit 2.

The number and the type of measurement sensors of which each subassembly is composed vary according to the position of the data acquisition unit with which these measurement sensors are associated and the size of the portion of length associated with the subassembly. By way of non-limiting example, if the consecutive data acquisition units are remote, the size of the portion of length associated with each subassembly may be between 50 and 500 metres.

The monitoring system therefore offers great flexibility since it is possible to adapt the composition of each subassembly of measurement sensors depending on the actual architecture of the distribution grid being monitored. For example, a choice may be made to place acoustic signal sensors in particular areas of the grid, such as the areas close to the accessories or the junctions.

In one possible embodiment of the system according to the invention, provision may be made for at least one subassembly of measurement sensors to comprise a plurality of measurement sensors of the same type which are spread over said portion of length.

Provision may also be made for a system in which at least one subassembly of measurement sensors comprises two or more temperature sensors and/or two or more acoustic signal sensors which are spread over said portion of length.

Preferably, all the subassemblies of measurement sensors comprise a plurality of temperature sensors which are spread over their respective portion of length. This makes it possible to have, at a lower cost, a large number of points for measuring the temperature along the cables. For example, for an assembly of cables 10 km in length, provision may be made:
to arrange a data acquisition unit every kilometer; and
for all the subassemblies of sensors to comprise temperature measurement sensors spread every 5 to 10 metres over a portion of length between 50 and 500 metres on just one side of the acquisition unit, or from 100 metres to one kilometer on either side of an acquisition unit.

Alternatively or in combination, provision may also be made for at least two subassemblies of measurement sensors of the system to comprise an inductive sensor configured to sense pulse events which are caused by partial discharges.

In any case, the measurement sensors of a given subassembly transmit their measurements to the data acquisition unit which is associated with them through a wired and/or wireless communication link (for example according to the Wi-Fi or Bluetooth protocol).

In one possible embodiment of the monitoring system according to the invention, each data acquisition unit 3ₐ, 3_{b}, 3_{c} is configured to transmit the received and preprocessed measurements to the central unit 2 via said one or more electric cables 1.

As illustrated in the non-limiting example in the FIGURE, the system also comprises a remote unit 6 with which the central unit 2 exchanges data via the Internet 7. In this case, the central unit 2 transmits data which are based on an aggregation of the received and preprocessed measurements to the remote unit 6.

1. A monitoring system for online monitoring of an assembly having one or more electric cables which are connected in series in an electrical distribution grid, the system comprising:
a central unit located on a portion of said assembly being monitored and a plurality of data acquisition units which are spread along said one or more electric cables in predefined positions,
wherein said system further comprises a plurality of subassemblies of measurement sensors, the measurement sensors of a given subassembly being associated with one and the same data acquisition unit and spread over at least one portion of the length of said one or more electric cables in the vicinity of said one and the same data acquisition unit, in that the number and the type of measurement sensors of a given subassembly vary according to the position of the data acquisition unit with which these measurement sensors are associated and the size of said portion of length, and in that each data acquisition unit is configured to receive and preprocess, during acquisition campaigns carried out under the command of the central unit, measurements originating from the measurement sensors which are associated with it in a given subassembly, and to transmit the received and preprocessed measurements to the central unit.\

2. The monitoring system according to claim 1, wherein at least one subassembly of measurement sensors comprises a plurality of measurement sensors of the same type which are spread over said portion of length.

3. The monitoring system according to claim 1, wherein at least one subassembly of measurement sensors comprises two or more temperature sensors and/or two or more acoustic signal sensors which are spread over said portion of length.

4. The monitoring system according to claim 1, wherein at least two subassemblies of measurement sensors comprise an inductive sensor configured to sense pulse events which are caused by partial discharges.

5. The monitoring system according to claim 1, wherein the measurement sensors of a given subassembly transmit their measurements to the data acquisition unit which is associated with them through a wired or wireless communication link.

6. The monitoring system according to claim 1, wherein each data acquisition unit is configured to transmit the received and preprocessed measurements to the central unit via said one or more electric cables.

7. The monitoring system according to claim 1, further comprising a remote unit with which the central unit exchanges data via the Internet, the central unit being configured to transmit data which are based on an aggregation of the received and preprocessed measurements.

8. The monitoring system according to claim 1, wherein the central unit is located on an end portion of said assembly being monitored.

9. The monitoring system according to claim 1, wherein two consecutive data acquisition units are separated by a distance of the order of one kilometer, and the size of said portion of length is between 50 and 500 metres.
